(19) United States
(12) Patent Application Publication
(10) Pub. No.: US 2026/0255576 A1
(43) Pub. Date: Aug. 27, 2026

(54) MEMORY DEVICES AND FABRICATING METHODS THEREOF

(71) Applicant: Yangtze Memory Technologies Co., Ltd., Wuhan (CN)

(72) Inventors: Junbo Feng, Wuhan (CN); Jianquan Jia, Wuhan (CN); Wenhao Xiong, Wuhan (CN); Bolun Wang, Wuhan (CN); Yu Gao, Wuhan (CN); Gang Liu, Wuhan (CN); Lei Jin, Wuhan (CN)

(21) Appl. No.: 19/067,318

(22) Filed: Feb. 28, 2025

(30) Foreign Application Priority Data
Feb. 24, 2025 (CN) 202510209106.0

(51) Int. Cl. H10B 12/00

(52) U.S. Cl. CPC H10B 12/315; H10B 12/0335; H10B 12/05; H10B 12/485

(57) ABSTRACT

A memory device includes an array of transistors. Each transistor includes a semiconductor layer extending along a first direction, a source region and a drain region located at two opposite ends of the semiconductor layer, and a gate stack structure coupled with the semiconductor layer and covering a middle region of the semiconductor layer between the source region and the drain region. The gate stack structure includes a first conductive layer coupled with the semiconductor layer, a second conductive layer coupled with the semiconductor layer and located above the first conductive layer along the first direction, and a first dielectric layer located between the first conductive layer and the second conductive layer.

### CROSS-REFERENCE TO RELATED APPLICATIONS

This application claims the benefit of priority to Chinese Application No. 202510209106.0, filed on Feb. 24, 2025, which is incorporated herein by reference in its entirety.

### TECHNICAL FIELD

The present disclosure generally relates to the field of semiconductor technology, and more particularly, to memory devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuit structures for facilitating operations of the memory array.

### SUMMARY

Some aspects of the present disclosure provide a memory device including an array of transistors, each transistor includes a semiconductor layer extending along a first direction, a source region and a drain region located at two opposite ends of the semiconductor layer, and a gate stack structure coupled with the semiconductor layer and covering a middle region of the semiconductor layer between the source region and the drain region. The gate stack structure includes a first conductive layer coupled with the semiconductor layer, a second conductive layer coupled with the semiconductor layer and located above the first conductive layer along the first direction, and a first dielectric layer located between the first conductive layer and the second conductive layer.

In some implementations, the first conductive layer is coupled with a first electrical source, and the second conductive layer is coupled with a second electrical source having a different electrical level from the first electrical source.

In some implementations, the memory device further includes a third conductive layer formed above a first side of the second conductive layer, the first side is away from the first conductive layer, and a second dielectric layer located between the second conductive layer and the third conductive layer.

In some implementations, the first conductive layer is coupled with a first electrical source; the second conductive layer is coupled with a second electrical source; and the third conductive layer is coupled with a third electrical source. The second electrical source has a different electrical level than the first electrical source or the third electrical source.

In some implementations, the memory device includes bit lines coupled to the source regions or the drain regions of the transistors and extending along a second direction, wherein the second direction is perpendicular to the first direction.

In some implementations, the memory device includes an array of storage units coupled with the transistors, respectively. The bit lines locate on a first side of the transistors and the storage units locate on a second side of the transistors opposite the first side along the first direction.

In some implementations, the memory device includes an array of storage units coupled with the transistors, respectively. The bit lines and the storage units are located on a first side and a second side of the transistors, the second side is opposite to the first side along the first direction and the bit lines and the storage units are arranged in an alternating pattern on each side.

In some implementations, the memory device includes a gate dielectric layer located between the semiconductor layer and the gate stack; and isolation walls arranged between two adjacent rows of vertical transistors in a second direction, wherein the second direction is perpendicular to the first direction.

In some implementations, a first distance between the gate dielectric layers of a first row of transistor and the isolation wall located adjacent to a first side of the first row of transistors is greater than 5 nm.

In some implementations, a second distance between the gate dielectric layers of a first row of transistor and the isolation wall located adjacent to a second side of the first row of transistors is greater than 0 nm, the second side is opposite to the first side in the second direction.

In some implementations, the memory device includes an array of storage units coupled with the transistors, respectively. The storage units arranged at two sides of the isolation wall are misaligned with each other.

In some implementations, the first conductive layer, the second conductive layer, and the third conductive layer have an equal thickness along the first direction.

In some implementations, a thickness of the second conductive layer is greater than a thickness of the first conductive layer and a thickness of the third conductive layer along the first direction.

In some implementations, a thickness of the second conductive layer is greater than or equal to a thickness of the first conductive layer along the first direction.

Some aspects of the present disclosure provide a memory device including an array of transistors that are parallelly connected and extending along a first direction; word lines each coupled to a row of the transistors arranged along a third direction; and first isolation walls arranged in an alternating pattern with the word lines at a second direction. The first direction, the third direction, and the second direction are perpendicular to each other. The word lines include a first conductive layer coupled to the transistors and a second conductive layer coupled to the transistors and being isolated with the first conductive layer by a first dielectric layer along the first direction.

In some implementations, the first conductive layer is coupled with a first electrical source; and the second conductive layer is coupled with a second electrical source having a different electrical level with the first electrical source.

In some implementations, the memory device includes a third conductive layer formed above a first side of the second conductive layer, the first side is away from the first conductive layer; and a second dielectric layer located between the second conductive layer and the third conductive layer.

In some implementations, the first conductive layer is coupled with a first electrical source; the second conductive layer is coupled with a second electrical source; and the third conductive layer is coupled with a third electrical source. The second electrical source has a different electrical level than the first electrical source or the third electrical source.

In some implementations, the memory device includes bit lines coupled to source regions or drain regions of the transistors and extending along a second direction perpendicular to the first direction and the third direction.

In some implementations, the memory device includes an array of storage units coupled with the transistors, respectively. The bit lines locate on a first side of the transistors; and the storage units locate on a second side of the transistors opposite to the first side along the first direction.

In some implementations, the memory device includes an array of storage units coupled with the transistors, respectively. The bit lines and the storage units are located on a first side and a second side of the transistors, the second side is opposite to the first side along the first direction; and the bit lines and the storage units are arranged in an alternating pattern on each side.

In some implementations, the transistor includes a semiconductor layer extending along the first direction and a gate dielectric layer located between the semiconductor layer and the word line coupled with the transistor; and the memory device further comprises isolation walls arranged between two adjacent rows of vertical transistors at a second direction, wherein the second direction is perpendicular to the first direction and the third direction.

In some implementations, a first distance between the gate dielectric layers of a first row of transistor and the isolation wall located adjacent to a first side of the first row of transistors is greater than 5 nm.

In some implementations, a second distance between the gate dielectric layers of a first row of transistor and the isolation wall located adjacent to a second side of the first row of transistors is greater than 0 nm, the second side is opposite to the first side in the second direction.

In some implementations, the memory device includes an array of storage units coupled with the transistors, respectively. The storage units arranged at two sides of the isolation wall are misaligned with each other.

In some implementations, the first conductive layer, the second conductive layer, and the third conductive layer have an equal thickness along the first direction.

In some implementations, a thickness of the second conductive layer is greater than a thickness of the first conductive layer and a thickness of the third conductive layer along the first direction.

In some implementations, a thickness of the second conductive layer is greater than or equal to a thickness of the first conductive layer along the first direction.

Some aspects of the present disclosure provide a method for fabricating a memory device, including: forming an array of transistors extending along a first direction, each transistor including a semiconductor layer and a source region and a drain region located at two opposite end of the semiconductor layer; forming a gate stack structure coupled with the semiconductor layer and covering a middle region of the semiconductor layer between the source region and the drain region. The gate stack structure includes a first conductive layer coupled to the transistors; a second conductive layer coupled to the transistors and located above the first conductive layer along the first direction; and a first dielectric layer located between the first conductive layer and the second conductive layer.

In some implementations, the gate stack structure includes a third conductive layer formed above a first side of the second conductive layer, the first side is away from the first conductive layer and a second dielectric layer located between the second conductive layer and the third conductive layer.

In some implementations, forming the gate stack structure includes forming a stacked structure including a first sacrificial layer, a second sacrificial layer, and the first dielectric layer located between the first sacrificial layer and the second sacrificial layer, and replacing the first sacrificial layer and the second sacrificial layer with a conductive material to form the first conductive layer and the second conductive layer.

In some implementations, forming the array of transistors includes forming holes penetrating the stacked structure along the first direction; filling the holes with the semiconductor layer and gate dielectric layers located between the semiconductor layer and the stacked structure.

In some implementations, the method further includes forming bit lines coupled to source regions or drain regions of the transistors and extending along a second direction, the second direction is perpendicular to the first direction.

In some implementations, the method further includes forming an array of storage units coupled with the transistors, respectively. The bit lines locate on a first side of the transistors; and the storage units locate on a second side of the transistors opposite the first side along the first direction.

In some implementations, the method further includes forming an array of storage units coupled with the transistors, respectively. The bit lines and the storage units are located on a first side and a second side of the transistors, the second side is opposite to the first side along the first direction, and the bit lines and the storage units are arranged in an alternating pattern on each side.

In some implementations, the method further includes forming first isolation walls arranged between two adjacent rows of vertical transistors in a second direction, wherein the second direction is perpendicular to the first direction.

In some implementations, a first distance between the gate dielectric layers of a first row of transistor and the isolation wall located adjacent to a first side of the first row of transistors is greater than 5 nm.

In some implementations, a second distance between the gate dielectric layers of a first row of transistor and the isolation wall located adjacent to a second side of the first row of transistors is greater than 0 nm, the second side is opposite to the first side in the second direction.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1A illustrates a schematic circuit diagram of a semiconductor device including an array of memory cells according to some implementations of the present disclosure.

FIG. 1B illustrates a schematic diagram of a semiconductor device, according to some implementations of the present disclosure.

FIG. 1C illustrates a top view of the semiconductor device in FIG. 1B, according to some implementations of the present disclosure.

FIG. 1D illustrates a partial cross-sectional view of the semiconductor device in FIG. 1B, according to some implementations of the present disclosure.

FIG. 1E illustrates a partial cross-sectional view of a semiconductor device, according to some implementations of the present disclosure.

FIG. 1F illustrates a partial cross-sectional view of a semiconductor device, according to some implementations of the present disclosure.

FIG. 2 illustrates a top view of a semiconductor device, according to some implementations of the present disclosure.

FIG. 3 illustrates a top view of a semiconductor device, according to some implementations of the present disclosure.

FIG. 4 illustrates a top view of a semiconductor device, according to some implementations of the present disclosure.

FIG. 5 illustrates a top view of a semiconductor device, according to some implementations of the present disclosure.

FIG. 6A illustrates a schematic diagram of a semiconductor device, according to some implementations of the present disclosure.

FIG. 6B illustrates a top view of the semiconductor device in FIG. 6A, according to some implementations of the present disclosure.

FIG. 7 illustrates a flowchart of a fabricating method for forming a semiconductor device, according to some implementations of the present disclosure.

FIGS. 8A-8I each illustrates a schematic view of the semiconductor device at a certain fabricating stage of the method shown in FIG. 7, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be used in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Drain-Induced Barrier Lowering (DIBL) is a short-channel effect commonly observed in field-effect transistors (FETs), particularly in nanometer-scale transistors. DIBL arises when a high drain voltage diminishes the potential barrier between the source and the drain. This reduction in the barrier leads to a decrease in the transistor's threshold voltage and an increase in subthreshold leakage current. As a result, power consumption rises, potentially compromising reliability. In 3D memory devices where memory cells (or memory layers) are stacked vertically in multiple layers for higher memory density, improved performance, and reduced footprint, the performance of the transistors in the corresponding memory cells is significantly impacted by DIBL.

For example, in vertical dynamic random access memory (DRAM) cells, a precise threshold voltage is critical for proper switching and retention of data. If DIBL lowers the threshold voltage of the transistor too much, it could cause unintended leakage current when the transistor is supposed to be off, leading to data corruption or unwanted conduction between the access transistor and the storage node (capacitor). This could result in incorrect charge retention and loss of data. Further, increased leakage current can cause increased noise in the bit line and interfere with data sensing, especially in read operations where the stored charge on the capacitor is sensitive. Additionally, excessive leakage can lead to faster charge loss from the storage capacitor, decreasing the retention time of the DRAM cell, which may reduce the overall refresh rate and affect cell stability. DRAM cells rely on the accurate reading of the charge stored in the capacitor. If the access transistor is improperly turned on (due to DIBL), it can cause incorrect reading of the stored data or data degradation. For example, if the access transistor is too leaky, it could allow charge to flow out of the capacitor during the read, disturbing the charge and potentially flipping the bit or causing errors in the data.

To address one or more of the aforementioned issues, the present disclosure introduces a memory device including an array of transistors. The transistor includes a gate stack structure including at least a first conductive layer and a second conductive layer isolated by a first dielectric layer. The first conductive layer, the first dielectric layer, and the second conductive layer are stacked along the first direction and coupled with a semiconductor layer of the transistor, i.e., the channel region of the transistor. For example, the first conductive layer is located adjacent to an end of the channel region, while the second conductive layer covers the middle of the channel region. As the first conductive layer and the second conductive layer are isolated by the first dielectric layer, they can be coupled to different voltage sources independently, so that the voltage applied to the middle of the channel region can be different from the voltage applied to the end of the channel region. For example, the voltage applied to the end of the channel region can be higher than the voltage applied to the middle of the channel region. Therefore, the potential barrier decrease at the end of the channel region would be greatly restrained while the gate control ability would not be affected. Compared with a gate structure formed by a single conductive material, the negative effects brought by DIBL are well suppressed, while the gate control capability of the vertical transistors remains unaffected.

Consistent with the scope of the present disclosure, according to some implementations of the present disclosure, the gate stack structure in the disclosed memory device further includes a third conductive layer coupled to the channel region and located above the second conductive layer along the first direction and a second dielectric layer located between the second conductive layer and the third conductive layer.

The first conductive layer, the second conductive layer, and the third conductive layer are stacked along the first direction and coupled with the channel region of the transistor, respectively. For example, the first conductive layer is located adjacent to a first end of the channel region, and the third conductive layer is located adjacent to a second end of the channel region, while the second conductive layer covers the middle of the channel region. As the first conductive layer, the second conductive layer, and the third conductive layer are isolated by the first dielectric layer and the second dielectric layer, they can be coupled to different voltage sources independently, so that the voltage applied to the middle of the channel region can be different with the voltage applied the two ends of the channel region. For example, the voltage applied to the ends of the channel region can be higher than the voltage applied to the middle of the channel region. The negative effects brought by DIBL would be well suppressed while the gate control capability of the vertical transistors remains unaffected.

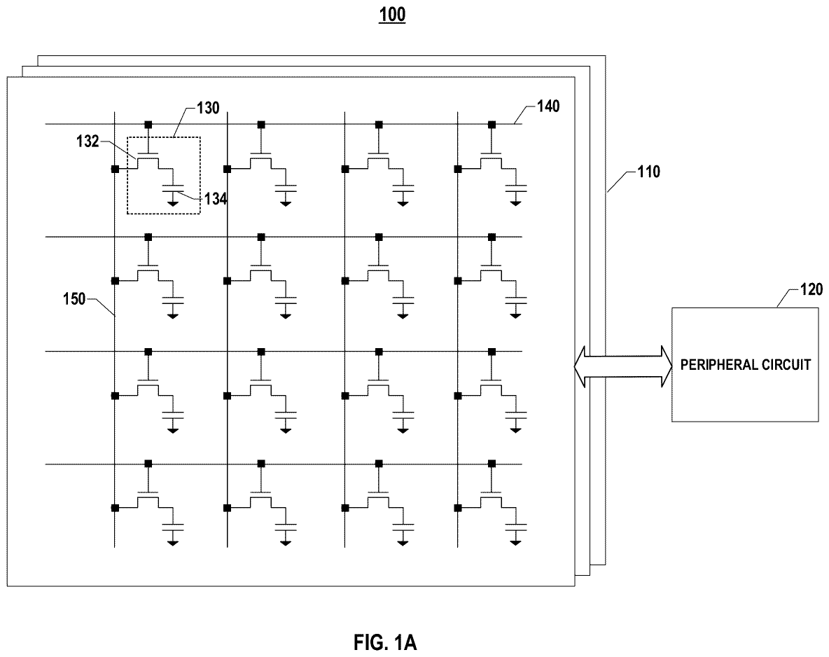

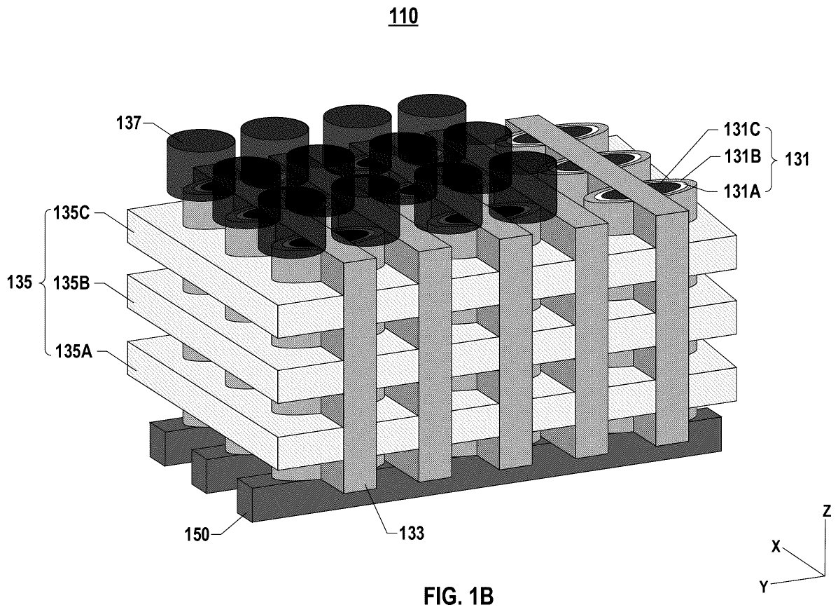

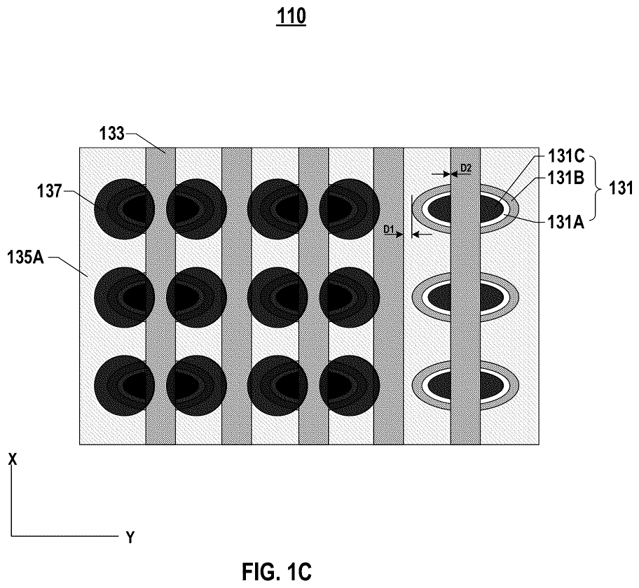

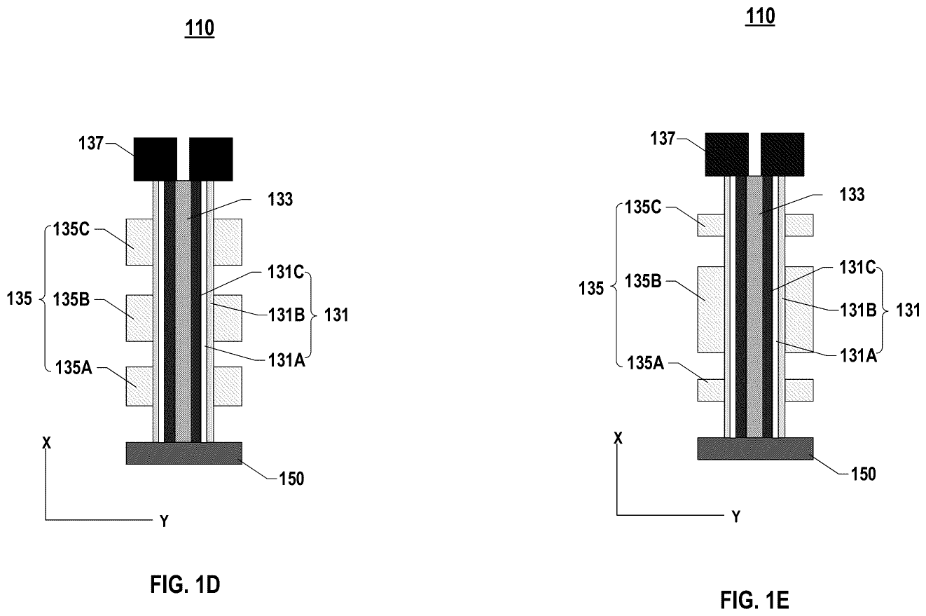

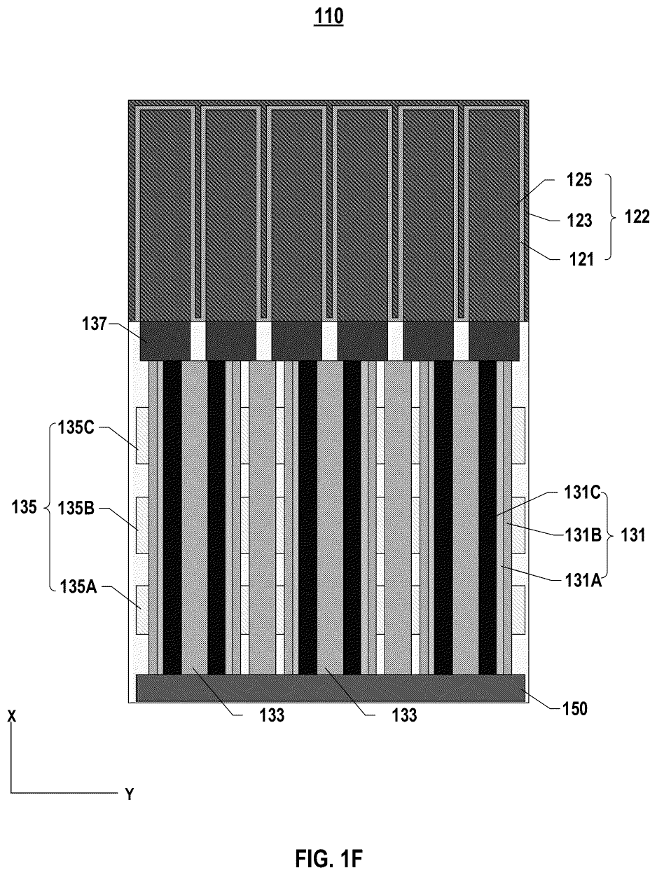

FIG. 1A illustrates a schematic diagram of a semiconductor device 100 including peripheral circuit structures and an array of memory cells each having a vertical transistor, according to some aspects of the present disclosure. Semiconductor device 100 can include a memory cell array 110 and peripheral circuit structures 120 coupled to memory cell array 110. Memory cell array 110 can be any suitable memory cell array in which each memory cell 130 includes a vertical transistor 132 and a storage unit 134 coupled to vertical transistor 132. In some implementations, memory cell array 110 is a DRAM cell array, and storage unit 134 is a capacitor for storing charge as the binary information stored by the respective DRAM cell. As shown in FIG. 1A, memory cells 130 can be arranged in a two-dimensional (2D) array having rows and columns. Peripheral circuit structures 120 can include any suitable digital, analog, and/or mixed-signal circuits used for facilitating the operations of the memory cell array. For example, the peripheral circuit structure can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuit structures 120 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations. Semiconductor device 100 can include word lines 140 coupling peripheral circuit structures 120 and memory cell array 110 for controlling the switch of vertical transistors 132 in memory cells 130 located in a row, as well as bit lines 150 coupling peripheral circuit structures 120 and memory cell array 110 for sending data to and/or receiving data from memory cells 130 located in a column. That is, each word line 140 is coupled to a respective row of memory cells 130, and each bit line 150 is coupled to a respective column of memory cells 130.

As shown in FIG. 1A, storage unit 134 can be coupled to the source or the drain of vertical transistor 132. Storage unit 134 can include any devices that are capable of storing binary data (e.g., 0 and 1), including but not limited to, capacitors for DRAM cells and FRAM cells, and PCM elements for PCM cells. Peripheral circuit structures 120 can be coupled to memory cell array 110 through bit lines 150, word lines 140, and any other suitable metal wirings. As described above, peripheral circuit structures 120 can include any suitable circuits for facilitating the operations of memory cell array 110 by applying and sensing voltage signals and/or current signals through word lines 140 and bit lines 150 to and from each memory cell 130. Peripheral circuit structures 120 can include various types of peripheral circuit structures formed using CMOS technologies.

In some embodiments, each memory cell 130 includes a storage unit 134 for storing a bit of data as a positive or negative electrical charge as well as one or more transistors (a.k.a. pass transistors) that control (e.g., switch and selecting) access to it. In some implementations, each memory cell is a one-transistor, one-capacitor (1T1C) cell. Since transistors always leak a small amount of charge, the capacitors will slowly discharge, causing information stored in them to drain. As such, a memory cell has to be refreshed to retain data, for example, by the peripheral circuit structure 120 coupled to the memory cell array 110, according to some implementations. In some implementations, storage unit 134 can be pillar capacitors which are formed after forming the vertical transistors 132. In some implementations, pillar capacitor refers to capacitor having a vertically oriented structure that resemble a pillar or a column. Pillar capacitors are typically formed by etching deep trenches into a substrate and then filling these trenches with conductive and dielectric materials to create the capacitor. Both the outer and inner surfaces of a pillar capacitor can be utilized as effective capacitor areas. This structure can be utilized to achieve greater packing density in a semiconductor device. In some other implementations, storage unit 134 can be cup capacitors, which are formed before forming the vertical transistors 132. In some implementations, cup capacitor refers to capacitor having a cup-like or bowl-like shape which are formed by creating a recessed area in the substrate, which is then lined with conductive and dielectric materials to form the capacitor. In such implementations, the high-temperature processes of forming the cup capacitors do not affect the formation of vertical transistors 132. Thus, metal oxide semiconductors can be employed as the channel structures of vertical transistors 132.

FIG. 1B illustrates a schematic diagram of memory cell array 110 in which storage unit is omitted, according to some implementations of the present disclosure. As shown in FIG. 1B, memory cell array 110 includes a plurality of vertical patterns 131 and a gate stack structure 135 including a plurality of conductive layers. Vertical patterns 131 extends along the first direction (the z-direction). A first end of vertical pattern 131 is coupled to a bit line 150, and a second end of vertical pattern 131 is coupled to a corresponding storage unit (not shown in FIG. 1B). The storage unit may be a pillar capacitors or cup capacitors according to different implementations. The storage unit may couple to the corresponding vertical patterns 131 through a contact 137, as shown in FIG. 1B. In some implementations, contact 137 can include conductive materials including, but not limited to W, Co, Cu, Al, TiN, TaN, polysilicon, silicides, or any combination thereof.

Memory cell array 110 can include a plurality of word lines each extending in a third direction (the x-direction) perpendicular to the first lateral direction (the y-direction). The word lines are coupled to a respective row of vertical transistors 132 and extend along a third direction, i.e., the x-direction. It is understood that gate stack structure 135 of vertical transistors 132 and corresponding word lines may be a continuous conductive structure in some examples. In other words, gate stack structure 135 of vertical transistors 132 may be part of the word lines, and the word lines may be an extension of corresponding gate stack structure 135. That is, gate stack structure 135 of adjacent vertical transistors 132 in the third direction are continuous. Gate stack structure 135 can be thus viewed as parts of a continuous structure extending in the third direction at which the continuous structure abut vertical transistors 132 in the same row on the same side.

In some implementations, the word lines of memory cell array 110 have a similar structure of the gate electrodes of gate stack structure 135. That is, the word line includes a first word line layer, a second word line layer, and a third word line layer that extends along the third direction, respectively. In some implementations, the first word line layer includes the first conductive layer 135A of the vertical transistor 132 that coupled with the word line, the first conductive layer 135A of each vertical transistor 132 may be part of the corresponding first word line layer. That is, the first word line layer may be an extension of corresponding first conductive layers 135A. In some implementations, the second word line layer includes the second conductive layer 135B of the vertical transistor 132 that coupled with the word line, the second conductive layer 135B of each vertical transistor 132 may be part of the corresponding second word line layer. That is, the second word line layer may be an extension of corresponding second conductive layers 135B. In some implementations, the third word line layer includes the third conductive layer 135C of the vertical transistor 132 that is coupled with the word line. The third conductive layer 135C of each vertical transistor 132 may be part of the corresponding third word line layer. That is, the third word line layer may be an extension of corresponding third conductive layers 135C.

Memory cell array 110 can also include a plurality of bit lines 150 each extending in a second direction (the y-direction) perpendicular to a third direction (the x-direction). It is understood that gate stack structure 135 and bit lines 150 may be formed in different lateral planes for ease of routing. In some implementations, bit lines 150 and storage unit are disposed on opposite sides of vertical transistor 132 in the first direction, which simplifies the routing of bit lines 150 and reduces the coupling capacitance between bit lines 150 and storage unit.

As shown in FIG. 1B, vertical transistor 132 includes a vertical pattern 131 with a semiconductor layer 131A, a gate dielectric layer 131B sandwiched between gate stack structure and semiconductor layer 131A. Gate dielectric layer 131B can include any suitable dielectric materials, such as silicon oxide, silicon nitride, silicon oxynitride, or high-k dielectrics. For example, gate dielectric layer 131B may include silicon oxide, i.e., gate oxide. In some implementations, gate dielectric layer 131B includes a high-k dielectric. In some implementations, vertical pattern 131 further includes an insulation core 131C surrounded by gate dielectric layer 131B, as shown in FIG. 1B. Insulation core 131C can include any suitable dielectric materials, such as silicon oxide, silicon nitride, silicon oxynitride, or a combination thereof. The leakage current of vertical transistor 132 could be greatly suppressed with the application of insulation core 131C.

Semiconductor layer 131A can include silicon (e.g., single crystalline silicon, c-Si), silicon germanium (SiGe), gallium arsenide (GaAs), germanium (Ge), silicon-on-insulator (SOI), or any other suitable materials. In some implementations, semiconductor layer 131A can include metal oxide and semiconductor materials, such as low-temperature polysilicon (LTPS) and indium gallium zinc oxide. In some implementations, semiconductor layer 131A can include one or more of indium gallium zinc oxide (InₓGa_{y}Zn_{z}O), indium gallium silicon oxide (InₓGa_{y}Si_{z}O), indium stannum zinc oxide (InₓSn_{y}Zn_{z}O), indium zinc oxide (InₓZn_{y}O), zinc oxide (ZnₓO), zinc stannum oxide (ZnₓSn_{y}O), zinc oxide nitride (ZnₓO_{y}N), zirconium zinc stannum oxide (ZrₓZn_{y}Sn_{z}O), stannum oxide (SnₓO), hafnium indium zinc oxide (HfₓIn_{y}Zn_{z}O), gallium zinc stannum oxide (GaₓZn_{y}Sn_{z}O), aluminum zinc stannum oxide (AlₓZn_{y}Sn_{z}O), ytterbium gallium zinc oxide (YbₓGa_{y}Zn_{z}O), indium gallium oxide (InₓGa_{y}O), etc.

As shown in FIG. 1B, vertical transistor 132 can further include a pair of a source and a drain (S/D, dope regions, a.k.a., source electrode and drain electrode) formed at the two ends of semiconductor layer 131A in the first direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by the gate structure in the first direction (the z-direction).

In some implementations, gate stack structure 135 of vertical transistor 132 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. In some implementations, gate stack structure 135 of vertical transistor 132 can include a first conductive layer 135A coupled with semiconductor layer 131A, a second conductive layer 135B coupled with semiconductor layer 131A and located above the first conductive layer 135A along the first direction, and a third conductive layer 135C formed above a first side of second conductive layer 135B, the first side is away from first conductive layer 135A. That is, first conductive layer 135A and third conductive layer 135C are located at two ends of the channel region on semiconductor layer 131A and are close to the source and drain of vertical transistor 132, respectively. Second conductive layer 135B is located between first conductive layer 135A and third conductive layer 135C along the first direction and is coupled with the middle of the channel region of semiconductor layer 131A. In some implementations, gate stack structure 135 further includes a first dielectric layer (not shown in FIG. 1B) located between first conductive layer 135A and second conductive layer 135B and a second dielectric layer (not shown in FIG. 1B) located between second conductive layer 135B and third conductive layer 135C. The first dielectric layer and the second dielectric layer are configured to isolate the conductive layers of gate stack structure 135 so that they can be coupled to different voltages independently.

In some implementations, first conductive layer 135A is coupled to a first electrical source, second conductive layer 135B is coupled to a second electrical source, and third conductive layer 135C is coupled to a third electrical source. The second electrical source has a different voltage level than the first electrical source or the third electrical source. In some implementations, the second electrical source has a lower voltage level than the first electrical source and the third electrical source. In this way, first conductive layer 135A and third conductive layer 135C would be coupled with a higher voltage level while second conductive layer 135B is coupled with a lower voltage level. The effects caused by the lower potential barrier due to the voltage difference between the source and drain of vertical transistor 132 could be offset by the voltage difference between the first conductive layer 135A and the second conductive layer 135B or the voltage difference between the third conductive layer 135C and the second conductive layer 135B.

In some implementations, for example, in a write operation, a voltage applied on the drain of vertical transistor 132 is higher than a voltage applied on the source of vertical transistors 132, and the potential barrier of the channel region close to the drain would be reduced due to the voltage difference. In this case, first conductive layer 135A is applied to a voltage level higher than the voltage level applied to second conductive layer 135B and third conductive layer 135C. Therefore, the potential barrier lower is offset, and the leakage generated by the barrier loss is suppressed. In some implementations, for example, in a read operation, a voltage applied on the source of vertical transistor 132 is higher than a voltage applied on the drain of vertical transistors 132, and the potential barrier of the channel region close to the source would be reduced due to the voltage difference. In this case, third conductive layer 135C is applied to a voltage level higher than the voltage level applied to second conductive layer 135B and first conductive layer 135A. Therefore, the potential barrier lower is offset, and the leakage generated by the barrier loss is suppressed.

In some implementations, referring to FIGS. 1B and 1C, memory cell array 110 further includes a plurality of isolation walls 133 arranged between two adjacent rows of vertical transistors 132 in the second direction. FIG. 1C illustrates a schematic to view of the semiconductor device in the x-y plane. Referring to FIG. 1C, isolation walls 133 are extending along a vertical plane perpendicular to the second direction. Two adjacent rows of vertical transistors 132 at the third direction are isolated by isolation walls 133, as shown in FIGS. 1B and 1C. In some implementations, referring to FIG. 1C, a first distance D1 between gate dielectric layers 131B of a first row of vertical transistors 132 and isolation wall 133 located adjacent to a first side of the first row of transistors 132 is greater than 5 nm, so that the gate stack structure 135 of the first row of vertical transistors 132 will not be cut off by the isolation wall 133 and could be coupled with a same word line signal. In some implementations, referring to FIG. 1C, a second distance D2 between gate dielectric layers 131B of a first row of vertical transistors 132 and isolation wall 133 located adjacent to a second side of the first row of transistors is greater than 0 nm. As shown in FIG. 1C, the second side is opposite to the first side in the second direction. As the gate stack structure 135 of the first row of vertical transistors 132 will not be cut off by the isolation wall 133 due to the existence of first distance D1, second distance D2 could be minimized to improve the density of memory cells array 110.

In some implementations, first conductive layer 135A, second conductive layer 135B, and third conductive layer 135C have an equal thickness along the first direction, as shown in FIG. 1D. In some implementations, first conductive layer 135A, second conductive layer 135B, and third conductive layer 135C have different thicknesses along the first direction. For example, the thickness of first conductive layer 135A is smaller than the thickness of second conductive layer 135B along the first direction, and the thickness of third conductive layer 135C is smaller than the thickness of second conductive layer 135B along the first direction. In some implementations, the thickness of first conductive layer 135A is equal to the thickness of third conductive layer 135C, which is smaller than the thickness of second conductive layer 135B, as shown in FIG. 1E. The thicknesses of first conductive layer 135A, second conductive layer 135B, and third conductive layer 135C can be designed based on the length of the channel region of vertical transistors 132 and the need for differentiated gate control capabilities. The implementations in the present disclosure are illustrative and should not be explained as limits to the present disclosure.

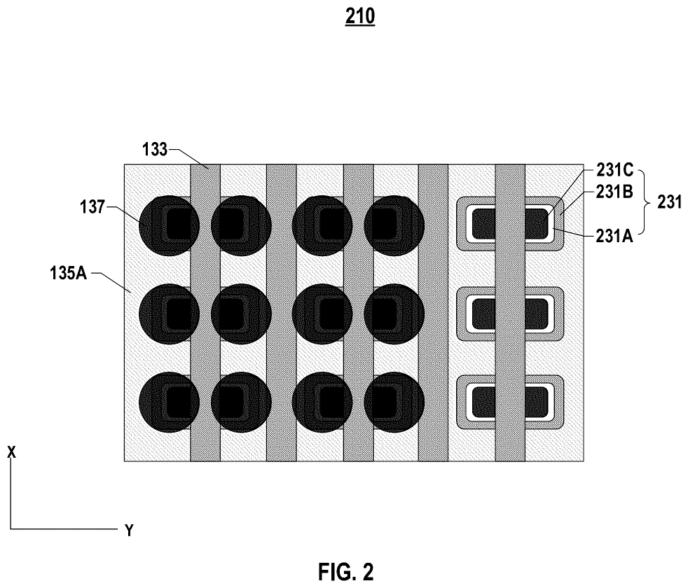

In some implementations, as shown in FIGS. 1B and 1C, for example, vertical patterns 131 can have a semi-circular or semi-elliptical shape with an arc-shaped side facing an isolation wall 133 on a first side and a liner-shaped side facing an isolation wall 133 on a second side. In some implementations, the arc-shaped side is in contact with gate stack structure 135 to gain a larger contact area compared to the liner-shaped side. It is understood that vertical patterns 131 may have any suitable shape, such as a rectangle shape, as shown in FIG. 2, FIG. 2 illustrates a schematic diagram of memory cell array 210, according to some implementations of the present disclosure. In some implementations, vertical patterns 231 includes a semiconductor layer 231A, a gate dielectric layer 231B, and an insulation core 231C. That is, the cross-section of vertical patterns 231 in the plan view (e.g., in the x-y plane) can have a square shape or a rectangular shape. It should be noted that vertical patterns 231 can have any other suitable shapes. The implementations in the present disclosure are illustrative and should not be explained as limits to the present disclosure.

FIG. 1F illustrates a cross-section diagram of memory cell array 110 in which storage units that coupled to the vertical patterns 131 through contact are shown, according to some implementations of the present disclosure. Memory cell array 110 may include a plurality of vertical transistors and storage units coupled with the vertical transistors correspondingly. In some implementations, the vertical transistors include a plurality of vertical patterns 131 and a gate stack structure 135 including a plurality of conductive layers. In some implementations, storage units can include vertical capacitors 122, as shown in FIG. 1F. Vertical capacitors 122 may be pillar capacitors, which can be formed after forming the vertical transistors 132. Vertical capacitors 122 may be cup capacitors, which are formed before forming the vertical transistors 132. In such implementations, the high-temperature processes of forming the cup capacitors do not affect the formation of vertical transistors 132. Thus, metal oxide semiconductors can be employed as the channel structures of vertical transistors 132.

Vertical capacitors 122 may include a first electrode 125 coupled with the corresponding vertical pattern 131, a capacitor dielectric 121 coupled with the first electrode 125, and a second electrode 123 coupled with the capacitor dielectric 121. That is, storage unit can be a vertical capacitor in which first and second electrodes and capacitor dielectric are stacked vertically (in the z-direction), and capacitor dielectric can be sandwiched between the first and second electrodes. In some implementations, each first electrode is coupled to source or drain of a respective vertical transistor 132 in the same memory cell, while all second electrodes are parts of a common plate coupled to the ground, e.g., a common ground.

It is understood that the structure and configuration of capacitor 122 are not limited to the example in FIG. 1F and may include any suitable structure and configuration, such as a planar capacitor, a stack capacitor, a multi-fins capacitor, a cylinder capacitor, a trench capacitor, or a substrate-plate capacitor. In some implementations, capacitor dielectric 121 includes dielectric materials, such as silicon oxide, silicon nitride, or high-k dielectrics including, but not limited to, Al₂O₃, HfO₂, Ta₂O₅, ZrO₂, TiO₂, or any combination thereof. It is understood that in some examples, capacitor 122 may be a ferroelectric capacitor used in a FRAM cell, and capacitor dielectric 121 may be replaced by a ferroelectric layer having ferroelectric materials, such as (PZT or SBT. In some implementations, first electrode 125 and second electrode 123 include conductive materials including, but not limited to W, Co, Cu, Al, TiN, TaN, polysilicon, silicides, or any combination thereof.

As shown in FIG. 1F, vertical pattern 131 extends vertically through and contacts gate stack structure, a lower end of vertical pattern 131 is in contact with bit line 150, and a higher end of vertical pattern 131 is in contact with contact 137 through which coupled with vertical capacitor 122, according to some implementations. That is, bit line 150 and vertical capacitor 122 can be disposed in different planes in the vertical direction and coupled to opposite ends of vertical pattern 131 in the vertical direction due to the vertical arrangement of memory cell 130. In some implementations, bit line 150 and vertical capacitor 122 are disposed on opposite sides of vertical patterns 131 in the vertical direction, which simplifies the routing of bit lines 150 and reduces the coupling capacitance between bit lines 150 and vertical capacitors 122.

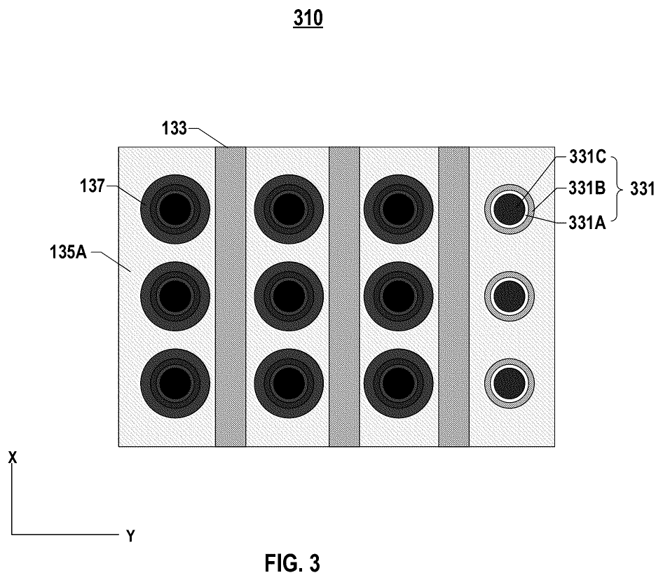

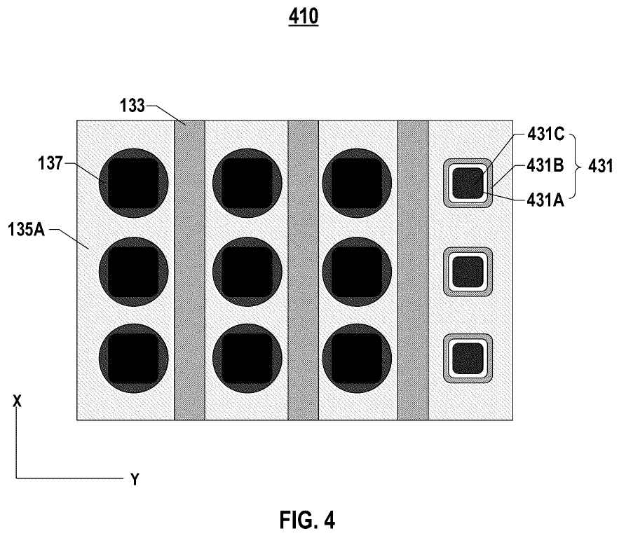

In some implementations, as shown in FIGS. 3 and 4, vertical transistors 132 can be Gate-All-Around (GAA) vertical transistors, in which the gate structure may surround the corresponding vertical pattern. FIG. 3 illustrates a schematic diagram of memory cell array 310, according to some implementations of the present disclosure. FIG. 4 illustrates a schematic diagram of memory cell array 410, according to some implementations of the present disclosure.

Referring to FIG. 3, memory cell array 310 is distinguished from memory cell array 110 in the structures of vertical patterns 231 and vertical patterns 331. In some implementations, vertical patterns 331 includes a semiconductor layer 331A, a gate dielectric layer 331B, and an insulation core 331C. Vertical patterns 331 distinguishes from vertical pattern 131 in that, vertical pattern 131 is partially surrounded by gate stack structure 135, while vertical pattern 331 is completely surrounded by gate stack structure 135. Memory cell array 310 also includes a plurality of isolation walls 133 arranged between two adjacent rows of vertical transistors 132 in the second direction. FIG. 3 illustrates a schematic view of the semiconductor device in the x-y plane. Referring to FIG. 3, isolation walls 133 are extending along a vertical plane perpendicular to the second direction. Two adjacent rows of vertical transistors 132 in the third direction are isolated by isolation walls 133. In some implementations, a first distance D1 between gate dielectric layers 331B of a first row of vertical transistors 132 and isolation wall 133 located adjacent to a first side of the first row of transistors 132 is greater than 5 nm, so that the gate stack structure 135 of the first row of vertical transistors 132 will not be cut off by the isolation wall 133 and could be coupled with a same word line signal. In some implementations, referring to FIG. 3, a second distance D2 between gate dielectric layers 331B of a first row of vertical transistors 132 and the isolation wall 133 located adjacent to a second side of the first row of transistors is greater than 5 nm. The second side is opposite the first side in the second direction.

It is understood that vertical patterns 331 may have any suitable shape, such as a rectangle shape, as shown in FIG. 4. FIG. 4 illustrates a schematic diagram of memory cell array 410, according to some implementations of the present disclosure. In some implementations, vertical patterns 431 includes a semiconductor layer 431A, a gate dielectric layer 431B, and an insulation core 431C. That is, the cross-section of vertical patterns 431 in the plan view (e.g., in the x-y plane) can have a square shape or a rectangular shape. It should be noted that vertical patterns 431 can have any other suitable shapes. The implementations in the present disclosure are illustrative and should not be explained as limits to the present disclosure.

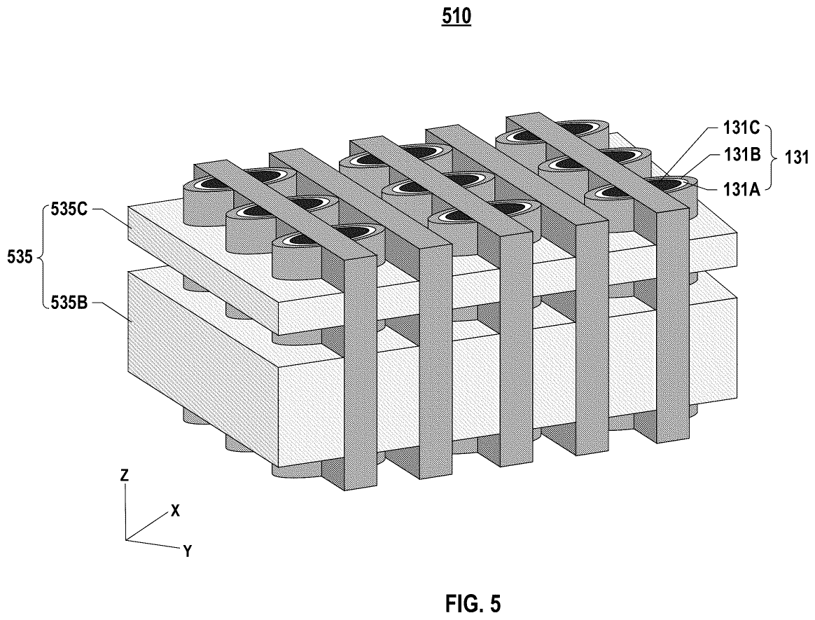

FIG. 5 illustrates a schematic diagram of a memory cell array 510 of semiconductor device 100, according to some implementations of the present disclosure. In some implementations, memory cell array 510 is distinguished from memory cell arrays 110 in the structures of gate stack structure 135 and gate stack structure 535, as shown in FIG. 1B and FIG. 5. The storage units and bit lines in memory cell array 510 are identical or similar to those found in memory cell array 110. Therefore, these elements are omitted from FIG. 5 to avoid reluctance.

Referring to FIG. 5, gate stack structure 535 of memory cell array 510 includes a second conductive layer 535B coupled with semiconductor layer 131A and a third conductive layer 535C formed above a first side of second conductive layer 535B, the first side is away from first conductive layer 535A. In some implementations, gate stack structure 535 further includes a second dielectric layer (not shown in FIG. 5) located between second conductive layer 535B and third conductive layer 535C. The second dielectric layer is configured to isolate the conductive layers of gate stack structure 535 so that they can be coupled to different voltages independently. As shown in FIG. 5, third conductive layer 535C is located at a first end of the channel region on semiconductor layer 131A and is close to one of the source and drain of vertical transistor 132. Second conductive layer 535B is located beneath third conductive layer 535C along the first direction and is coupled with the middle of the channel region and a second end of semiconductor layer 131A that is close to the other one, the source and drain of vertical transistor 132.

In some implementations, second conductive layer 535B is coupled to a second electrical source, and third conductive layer 535C is coupled to a third electrical source. The second electrical source has a different voltage level than the third electrical source. In some implementations, the second electrical source has a lower voltage level than the third electrical source. In this way, third conductive layer 535C would be coupled with a higher voltage level while second conductive layer 535B is coupled with a lower voltage level. The effects caused by the lower potential barrier due to the voltage difference between the source and drain of vertical transistor 132 could be offset by the voltage difference between the third conductive layer 535C and the second conductive layer 535B.

In some implementations, second conductive layer 535B, and third conductive layer 535C have different thicknesses along the first direction. For example, the thickness of third conductive layer 135C is smaller than the thickness of second conductive layer 135B along the first direction, as shown in FIG. 5. The thicknesses of the second conductive layer 135B and third conductive layer 135C can be designed based on the length of the channel region of vertical transistors 132 and the needs for differentiated gate control capabilities. The implementations in the present disclosure are illustrative and should not be explained as limits to the present disclosure.

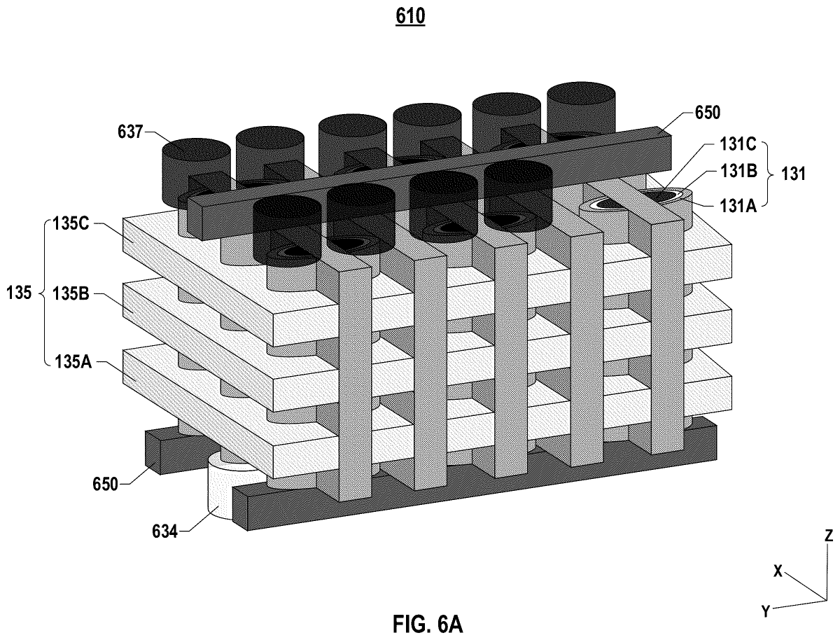

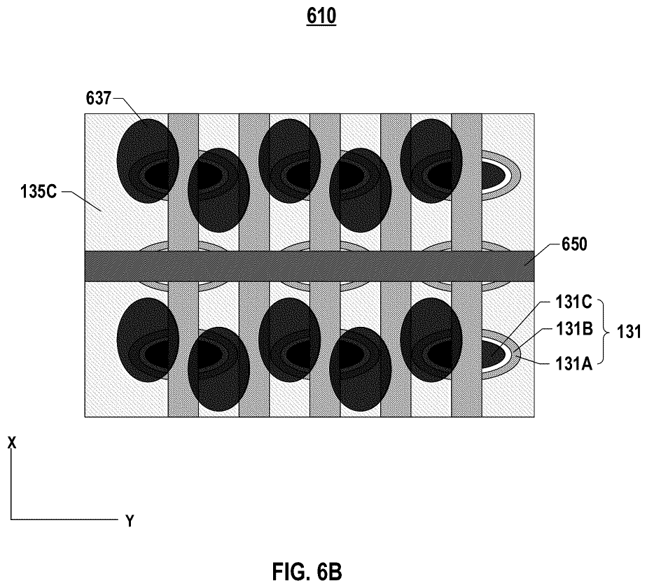

FIG. 6A illustrates a schematic diagram of a memory cell array 610 of semiconductor device 100 in which the storage units are omitted, FIG. 6B illustrates a top view of memory cell array 610, according to some implementations of the present disclosure. Memory cell array 610 is distinguished from memory cell arrays 110 in the arrangement of the storage units 634 and the bit lines 650, as shown in FIG. 6A. To ease description, the storage units are not illustrated in FIG. 6A. It should be understood that the storage unit may couple with vertical pattern 131 through contacts 637, as shown in FIG. 6A. In some implementations, storage units and bit lines 150 are located at two sides of vertical transistors 132 in the first direction, as shown in FIG. 1F. In some implementations, bit lines 650 and storage units are located on a first side and a second side of transistors 132. The second side is opposite the first side along the first direction. As shown in FIGS. 6A and 6B, bit lines 650 and contacts 637 are arranged in an alternating pattern on each of the first side and the second side so that bit lines 650 and the storage units are arranged in an alternating pattern on each of the first side and the second side.

To avoid interference between two adjacent storage units of memory cell array 110, the storage units are isolated by dielectric layers. Additionally, a minimum distance between neighboring storage units must be maintained to mitigate the risk of parasitic effects. Therefore, the cross-sectional area of the storage units cannot be maximized, which limits the storage capacity of the memory device. To address this question, as shown in FIGS. 6A and 6B, bit lines 650 and storage units are arranged in a mixed pattern at the two sides of vertical transistors 132 at the first direction. There is no specific requirement for the size of bit lines 650, and the width of bit lines 650 in the third direction can be minimized to save more space for contacts 637 and corresponding storage units. Therefore, the cross-sectional area of the storage units can be greatly increased compared to the cross-sectional area of storage units as shown in FIG. 1B.

In some implementations, referring to FIGS. 6A and 6B, memory cell array 610 further includes a plurality of isolation walls 133 arranged between two adjacent rows of vertical transistors 132 in the second direction. Referring to FIG. 6B, isolation walls 133 are extending along a vertical plane perpendicular to the second direction. Two adjacent rows of vertical transistors 132 in the third direction are isolated by isolation walls 133. In some implementations, contacts 637 and corresponding storage units arranged at two sides of isolation wall 133 are misaligned with each other, as shown in FIG. 634. The malignant of contacts 637 could further increase the cross-sectional area of the storage units without reducing the minimal distance between two adjacent storage units.

The present disclosure further provides a method for fabricating a memory device. The method includes forming an array of transistors extending along the first direction, each transistor includes a semiconductor layer and a source region and a drain region located at two opposite end of the semiconductor layer. The method further includes forming a gate stack structure coupled with the semiconductor layer and covering a middle region of the semiconductor layer between the source region and the drain region. The gate stack structure includes a first conductive layer coupled to the transistors, a second conductive layer coupled to the transistors and located above the first conductive layer along the first direction, and a third conductive layer formed above a first side of the second conductive layer, the first side is away from the first conductive layer. The gate stack structure further includes a first dielectric layer located between the first conductive layer and the second conductive layer, and a second dielectric layer located between the second conductive layer and the third conductive layer.

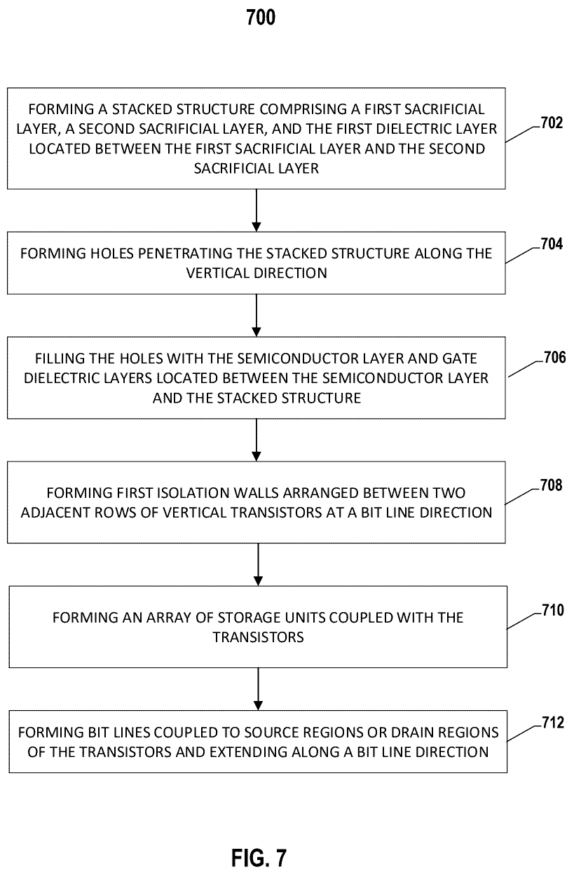

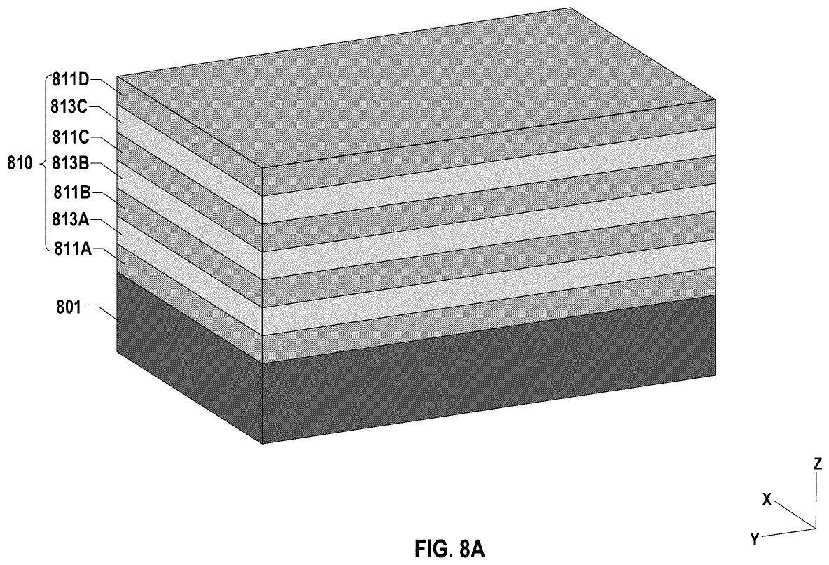

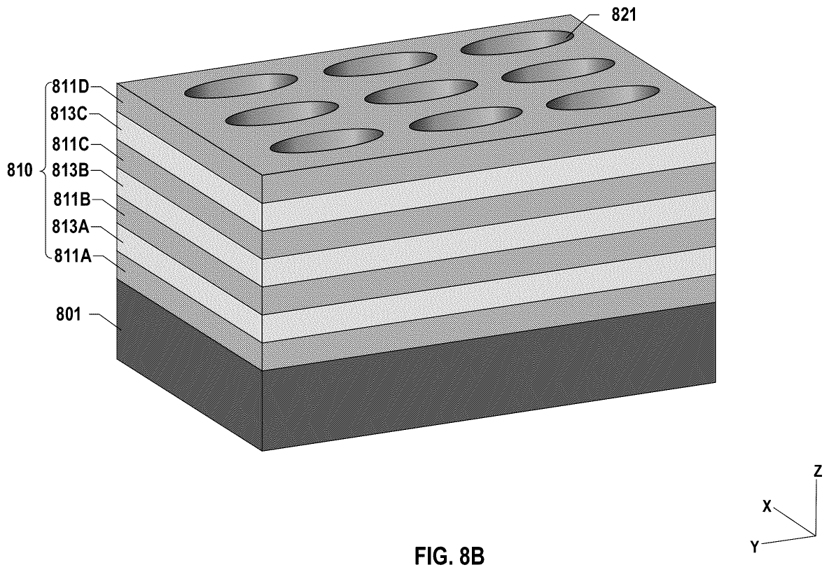

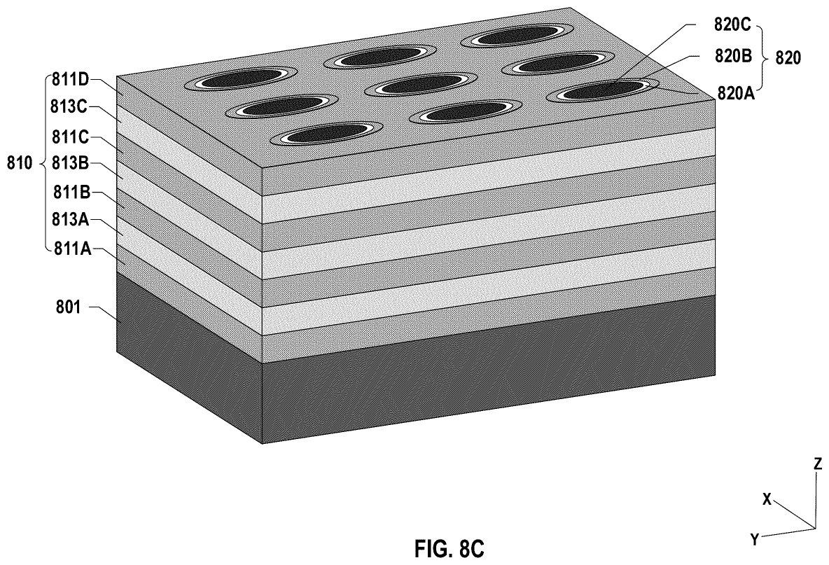

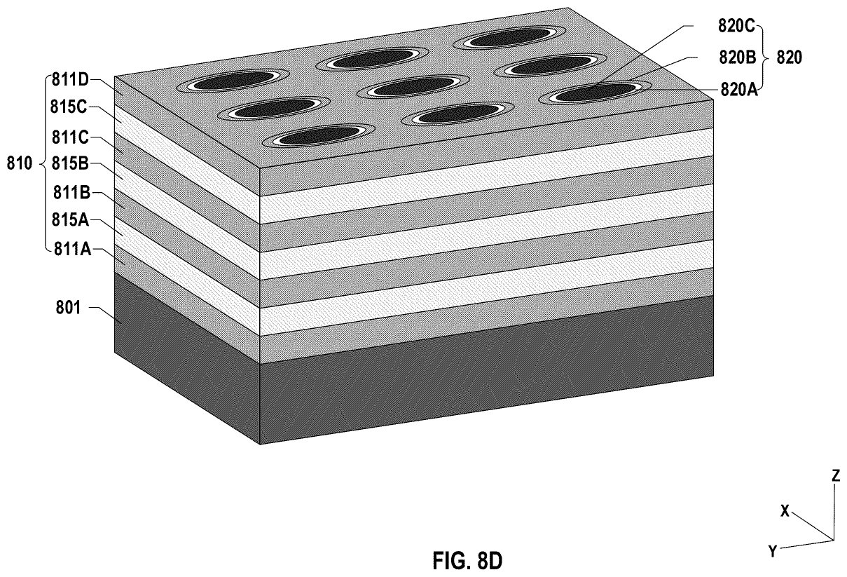

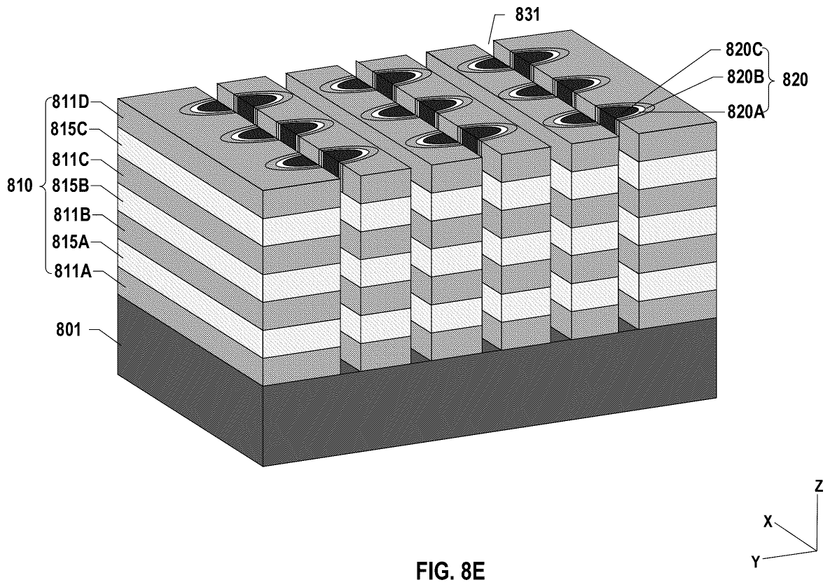

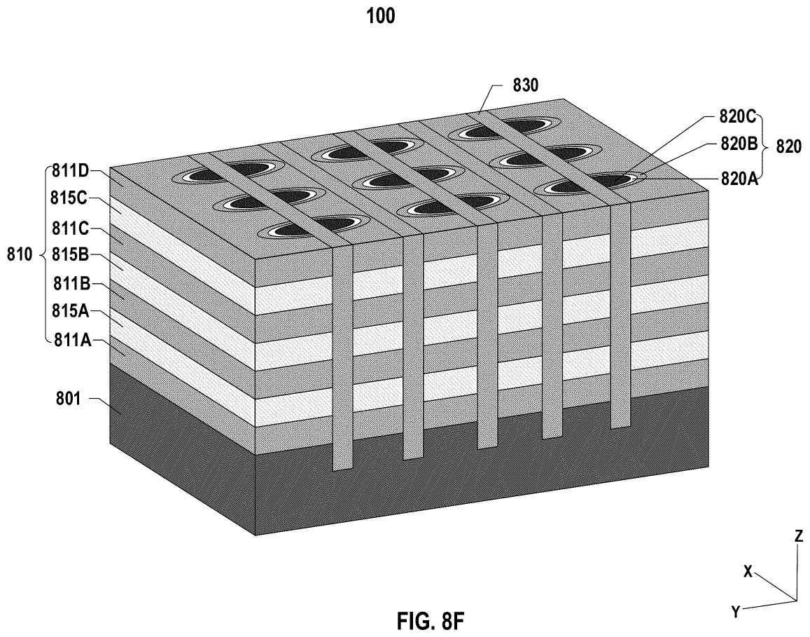

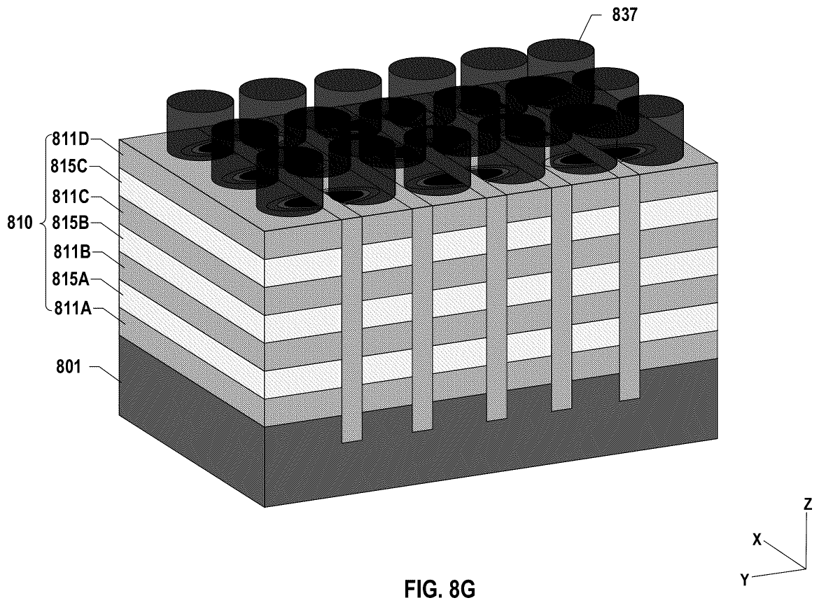

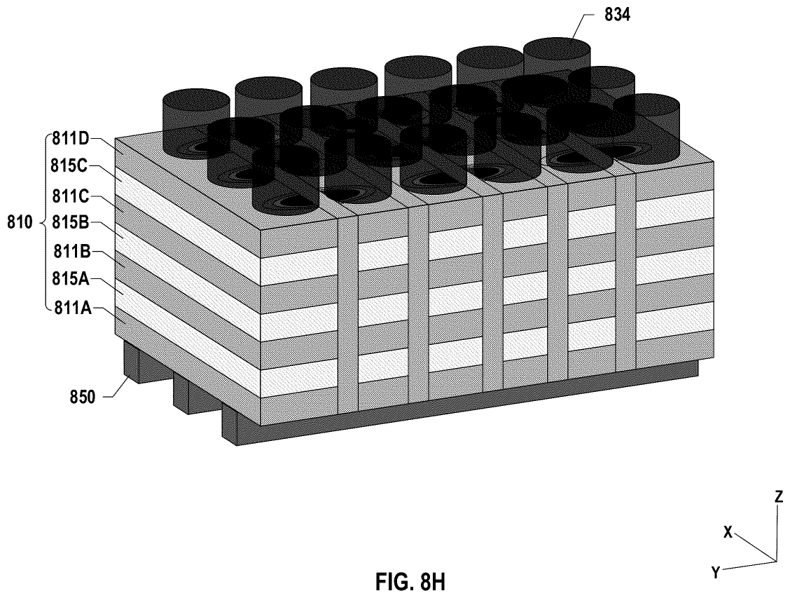

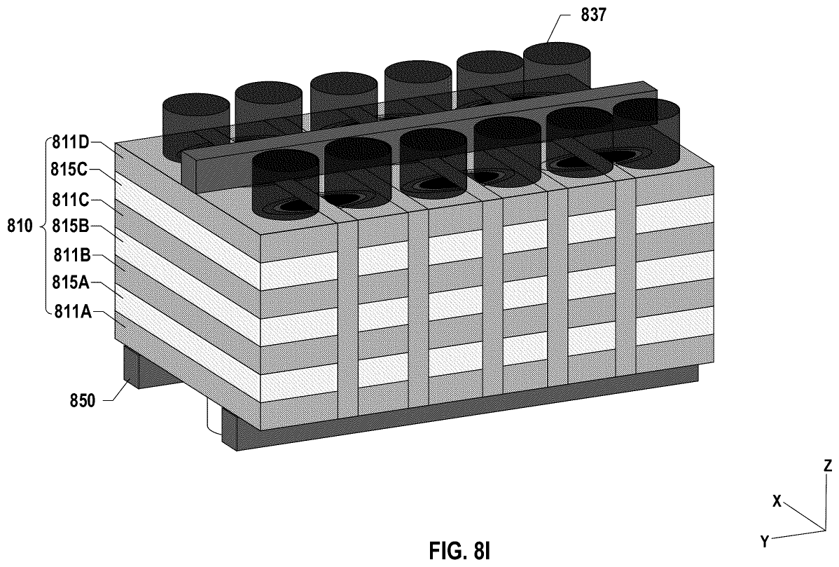

FIG. 7 illustrates a flowchart of a fabricating method 700 for forming a memory structure, according to some implementations of the present disclosure. FIGS. 8A-8J illustrate schematic views of a semiconductor device at certain fabricating stages of method 700 shown in FIG. 7, according to various implementations of the present disclosure. It is understood that the operations shown in method 700 are not exhaustive and that other operations can be performed as well before, after, or between any of the illustrated operations. Further, some of the operations may be performed simultaneously, or in a different order than shown in FIG. 7.

As shown in FIGS. 7 and 8A, method 700 can start at operation 702, in which a stacked structure 810 is formed on a substrate 801. In some implementations, the substrate 801 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials.

In some implementations, stacked structure 810 forms the gate stack structure of vertical transistors 132, and includes a stack of conductive layers and dielectric layers arranged alternatively along the first direction. The dielectric layers can include any suitable dielectric materials, such as silicon oxide, silicon nitride, silicon oxynitride, or high-k dielectrics. Conductive layers can include any suitable conductive materials, such as polysilicon, metals (e.g., W, Cu, Al, etc.), metal compounds (e.g., TiN, TaN, etc.), or silicide. For example, conductive layers may include doped polysilicon, i.e., a gate poly. In some implementations, gate electrode includes multiple conductive layers, such as a W layer over a TiN layer.

In some implementations, stacked structure 810 includes a stack of sacrificial layers and dielectric layers arranged alternatively along the first direction. The sacrificial layers will be replaced by conductive layers after the semiconductor layers are formed. Referring to FIG. 8A, FIG. 8A illustrates a schematic view of a semiconductor device after stacked structure 810 being formed. Stacked structure 810 includes a first sacrificial layer 813A, a second sacrificial layer 813B, and a third sacrificial layer 813C arranged along the first direction. Stacked structure 810 further includes a first dielectric layer 811A, a second dielectric layer 811B, a third dielectric layer 811C, and a fourth dielectric layer 811D arranged alternatively with the sacrificial layers in the first direction. The sacrificial layers include any suitable dielectric materials having a different etching ratio with the dielectric layers. For example, the first dielectric layer 811A, the second dielectric layer 811B, and the third dielectric layer 811C, and the fourth dielectric layer 811D include silicon oxide, while the first sacrificial layer 813A, the second sacrificial layer 813B, and the third sacrificial layer 813C are made of silicon nitride.

In some implementations, the stacked structure 810 can be formed by a series of fabricating processes including thin film deposition processes (e.g., chemical vapor deposition (CVD), physical vapor deposition (PVD), atomic layer deposition (ALD), etc.) and patterning processes (e.g., photoetching, dry etching, wet etching, cleaning, chemical mechanical polishing (CMP), etc.

As shown in FIG. 7, method 700 can proceed to operation 704, in which a plurality of holes 821 penetrating stacked structure 810 is formed along the first direction. The plurality of holes 821 are configured to form vertical patterns therein. FIG. 8B illustrates a schematic view of the semiconductor device after the plurality of holes 821 are formed.

In some implementations, stacked structure 810 includes a plurality of layers made of different materials, as shown in FIGS. 8A and 8B. Therefore, a selective manner would be needed to create holes 821. For example, a wet etch (e.g., buffered oxide etch, BOE) or a dry etch (e.g., reactive ion etching, RIE) is implied to etch fourth dielectric layer 811D (made of silicon oxide) selectively. Silicon oxide can be etched relatively easily with a buffered HF solution or specific gas chemistries in RIE. After fourth dielectric layer 811D is etched, third sacrificial layer 813C (made of silicon nitride) is then etched selectively. Silicon nitride is more difficult to etch compared to silicon oxide due to its hardness and chemical resistance and may be etched using RIE with an appropriate gas mixture (e.g., CF₄, S₆6, or Cl₂-based chemistries). RIE can etch the nitride material selectively without significantly affecting the underlying oxide. The sacrificial layers and dielectric layers of stacked structure 810 can be etched alternatively until substrate 801 is exposed from holes 821, as shown in FIG. 8B.

As shown in FIG. 7, method 700 can proceed to operation 704, in which vertical patterns 820 is formed in holes 821 correspondingly. FIG. 8C illustrates a schematic view of the semiconductor device after vertical patterns 820 are formed.

In some implementations, vertical pattern 820 includes a semiconductor layer 820A, a gate dielectric layer 820B sandwiched between gate stack structure and semiconductor layer 820A. Gate dielectric layer 820B can include any suitable dielectric materials, such as silicon oxide, silicon nitride, silicon oxynitride, or high-k dielectrics. For example, gate dielectric layer 820B may include silicon oxide, i.e., gate oxide. In some implementations, gate dielectric layer 820B includes a high-k dielectric. In some implementations, vertical pattern 820 further includes an insulation core 820C surrounded by gate dielectric layer 820B, as shown in FIG. 8C. Insulation core 820C can include any suitable dielectric materials, such as silicon oxide, silicon nitride, silicon oxynitride, or a combination thereof. The leakage current of vertical transistor 132 could be greatly suppressed with the application of insulation core 820C.

Semiconductor layer 820A can include silicon (e.g., single crystalline silicon, c-Si), silicon germanium (SiGe), gallium arsenide (GaAs), germanium (Ge), silicon-on-insulator (SOI), or any other suitable materials. In some implementations, semiconductor layer 131A can include metal oxide and semiconductor materials, such as low-temperature polysilicon (LTPS) and indium gallium zinc oxide. In some implementations, semiconductor layer 820A can include one or more of indium gallium zinc oxide (InₓGa_{y}Zn_{z}O), indium gallium silicon oxide (InₓGa_{y}Si_{z}O), indium stannum zinc oxide (InₓSn_{y}Zn_{z}O), indium zinc oxide (InₓZn_{y}O), zinc oxide (ZnₓO), zinc stannum oxide (ZnₓSn_{y}O), zinc oxide nitride (ZnₓO_{y}N), zirconium zinc stannum oxide (ZrₓZn_{y}Sn_{z}O), stannum oxide (SnₓO), hafnium indium zinc oxide (HfₓIn_{y}Zn_{z}O), gallium zinc stannum oxide (GaₓZn_{y}Sn_{z}O), aluminum zinc stannum oxide (AlₓZn_{y}Sn_{z}O), ytterbium gallium zinc oxide (YbₓGa_{y}Zn_{z}O), indium gallium oxide (InₓGa_{y}O), etc.

As shown in FIG. 8C, vertical transistor 132 can further include a pair of a source and a drain (S/D, dope regions, a.k.a., source electrode and drain electrode) formed at the two ends of semiconductor layer 820A in the first direction (the z-direction), respectively. For example, the source region can be formed by the region of semiconductor layer 820A covered by fourth dielectric layer 811D, and the drain region can be formed by the region of semiconductor layer 820A covered by first dielectric layer 811A. The source and drain can be doped with any suitable P-type dopants, such as boron (B) or Gallium (Ga), or any suitable N-type dopants, such as phosphorus (P) or arsenic (As). The source and drain can be separated by the gate structure in the first direction (the z-direction).

As shown in FIG. 7, method 700 can proceed to operation 706, in which the sacrificial layers are replaced by conductive layers respectively. FIG. 8D illustrates a schematic view of the semiconductor device after the sacrificial layers are replaced.

As shown in FIG. 8C, first sacrificial layer 813A, second sacrificial layer 813B, and third sacrificial layer 813C are removed first. In some implementations, the sacrificial layers can be removed by an appropriate etching process, typically wet etching using hydrofluoric acid (HF) or a BOE. In some implementations, dry etching (RIE) with a suitable gas mixture may be used to remove silicon oxide or other material of the sacrificial layers. Then the conductive layers can be formed in the space occupied by the sacrificial layers respectively. For example, a conductive material, such as tungsten (W), copper (Cu), aluminum (Al), metal compounds (e.g., titanium nitride (TiN), tantalum nitride (TaN), or silicide, is often deposited using chemical vapor deposition (CVD) or physical vapor deposition (PVD). In some implementations, for tungsten to be formed, Tungsten CVD (using a precursor like WF6) is commonly used. As shown in FIG. 8D, a first conductive layer 815A is formed between first dielectric layer 811A and second dielectric layer 811B, a second conductive layer 815B is formed between second dielectric layer 811B and third dielectric layer 811C, and a third conductive layer 815C is formed between third dielectric layer 811C and fourth dielectric layer 811D. The conductive layers may be formed by same material or different materials.

As shown in FIG. 7, method 700 can proceed to operation 708, in which isolation walls 830 are formed between two adjacent rows of vertical transistors in the second direction to prevent electrical interference or crosstalk between adjacent transistors. FIGS. 8E and 8F illustrate schematic views of the semiconductor device during the fabrication of isolation walls 830.

In some implementations, a plurality of isolation trenches 831 are formed in the semiconductor device along the third direction using photolithography and etching processes. For example, a layer of photoresist is applied to the surface of the semiconductor device and exposed to UV light through a photomask with the desired trench pattern. The exposed photoresist will harden, and the unexposed areas will be washed away in the development process. The photoresist pattern acts as a mask for the next etching step. After photolithography, the semiconductor device undergoes etching to create isolation trenches 831 using dry etching (reactive ion etching, RIE) or wet etching. RIE is commonly used because it offers good selectivity, vertical trench profiles, and precision. The depth of isolation trenches 831 depends on the depth of the stacked structure 810 and the requirements of the isolation. In some implementations, isolation trenches 831 penetrates stacked structure 810, as shown in FIG. 8E. In some implementations, isolation trenches 831 may extend into substrate 801.

Isolation walls 830 are then formed in isolation trenches 831, as shown in FIG. 8F. After isolation trenches 831 have been etched, they are typically filled with insulation material, such as silicon oxide, silicon nitride, or other dielectrics. The filling can be done by CVD, PVD, ALD, or any other suitable processes. A CMP may be used to polish the surface of the semiconductor device after isolation walls 830 are formed to remove any excess material from the top surface and ensure isolation walls 830 are filled flush with the semiconductor device. Referring to FIG. 8F, isolation walls 830 are extending along a vertical plane perpendicular to the second direction. Two adjacent rows of vertical transistors at the third direction are isolated by isolation walls 830. In some implementations, referring to FIG. 8E, a first distance D1 between gate dielectric layers 820B of a first row of vertical transistors 132 and isolation wall 830 located adjacent to a first side of the first row of transistors 132 is greater than 5 nm, so that the gate stack structure of the first row of vertical transistors 132 will not be cut off by the isolation wall 830 and could be coupled with a same word line signal. In some implementations, a second distance D2 between gate dielectric layers 820B of a first row of vertical transistors 132 and isolation wall 830 located adjacent to a second side of the first row of transistors is greater than 0 nm. The second side is opposite the first side in the second direction. As the gate stack structure of the first row of vertical transistors 132 will not be cut off by the isolation wall 830 due to the existence of first distance D1, second distance D2 could be minimized to improve the density of memory cells array 110.

As shown in FIG. 7, method 700 can proceed to operation 710, in which a plurality of storage units (not shown) are formed to couple with the vertical transistors respectively at the first direction. FIG. 8G illustrates a schematic view of the semiconductor device after storage units 834 are formed.

As shown in FIG. 8G, storage unit can be coupled to the source or the drain of vertical transistor 132 through corresponding contact 837. In some embodiments, each memory cell 130 includes a storage unit for storing a bit of data as a positive or negative electrical charge as well as one or more transistors (a.k.a. pass transistors) that control (e.g., switch and selecting) access to it. In some implementations, each memory cell is a one-transistor, one-capacitor (1T1C) cell. In some implementations, the storage unit may be pillar capacitors, which can be formed after forming the vertical patterns. The storage unit may be cup capacitors, which are formed before forming the vertical transistors. In such implementations, the high-temperature processes of forming the cup capacitors do not affect the formation of vertical patterns. Thus, metal oxide semiconductors can be employed as the channel structures of vertical patterns. The storage units may include vertical capacitors including a first electrode coupled with the corresponding vertical patterns, a capacitor dielectric coupled with the first electrode, and a second electrode coupled with the capacitor dielectric. That is, the storage unit can be a vertical capacitor in which first and second electrodes and capacitor dielectric are stacked vertically (in the z-direction), and capacitor dielectric can be sandwiched between the first and second electrodes. In some implementations, each first electrode is coupled to source or drain of a respective vertical transistor in the same memory cell, while all second electrodes are parts of a common plate coupled to the ground, e.g., a common ground. In some implementations, the capacitor dielectric includes dielectric materials, such as silicon oxide, silicon nitride, or high-k dielectrics including, but not limited to, Al₂O₃, HfO₂, Ta₂O₅, ZrO₂, TiO₂, or any combination thereof. It is understood that in some examples, the vertical capacitor may be a ferroelectric capacitor used in a FRAM cell, and capacitor dielectric may be replaced by a ferroelectric layer having ferroelectric materials, such as (PZT or SBT. In some implementations, the first electrode and the second electrode include conductive materials including, but not limited to W, Co, Cu, Al, TiN, TaN, polysilicon, silicides, or any combination thereof.

As shown in FIG. 7, method 700 can proceed to operation 712, in which a plurality of bit lines 850 are formed to couple with the vertical transistors respectively in the first direction. FIG. 8H illustrates a schematic view of the semiconductor device after the storage units are formed. In some implementations, substrate 801 is removed to expose a second side of stacked structure 810 and vertical patterns 820. Referring to FIG. 8H, bit lines 850 extend along the second direction and are coupled with one side of semiconductor layer 820A.

In some implementations, the storage units and bit lines 850 are located at two sides of vertical transistors 132 at the first direction, as shown in FIG. 8H. In some implementations, bit lines 850 and the storage units are located on a first side and a second side of transistors 132. The second side is opposite to the first side along the first direction. As shown in FIG. 8I, bit lines 850 and the storage units (not shown)are arranged in an alternating pattern on each of the first side and the second side. The storage units are coupled with corresponding vertical patterns through contacts 837, as shown in FIG. 8I. In some implementations, bit lines 850 and the storage units are arranged in a mixed pattern at the two sides of vertical transistors in the first direction, and the cross-sectional area of storage units 834 can be increased to suppress parasitic effects.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations but should be defined only in accordance with the following claims and their equivalents.

What is claimed is:

1. A memory device comprising an array of transistors, each transistor comprising:
a semiconductor layer extending along a first direction;
a source region and a drain region located at two opposite ends of the semiconductor layer; and
a gate stack structure coupled with the semiconductor layer and covering a middle region of the semiconductor layer between the source region and the drain region; wherein
the gate stack structure comprises:
a first conductive layer coupled with the semiconductor layer;
a second conductive layer coupled with the semiconductor layer and located above the first conductive layer along the first direction; and
a first dielectric layer located between the first conductive layer and the second conductive layer.

2. The memory device of claim 1, wherein
the first conductive layer is coupled with a first electrical source; and
the second conductive layer is coupled with a second electrical source having a different electrical level from the first electrical source.

3. The memory device of claim 1, further comprising:
a third conductive layer formed above a first side of the second conductive layer, the first side is away from the first conductive layer; and
a second dielectric layer located between the second conductive layer and the third conductive layer.

4. The memory device of claim 3, wherein
the first conductive layer is coupled with a first electrical source;
the second conductive layer is coupled with a second electrical source; and
the third conductive layer is coupled with a third electrical source;
wherein the second electrical source has a different electrical level than the first electrical source or the third electrical source.

5. The memory device of claim 1, further comprising:
bit lines coupled to the source regions or the drain regions of the transistors and extending along a second direction, wherein the second direction is perpendicular to the first direction; and
an array of storage units coupled with the transistors, respectively; wherein
the bit lines locate on a first side of the transistors and the storage units locate on a second side of the transistors opposite the first side along the first direction; or
the bit lines and the storage units are located on a first side and a second side of the transistors, the second side being opposite to the first side along the first direction and the bit lines and the storage units are arranged in an alternating pattern on each side.

6. The memory device of claim 1, further comprising:
a gate dielectric layer located between the semiconductor layer and the gate stack; and
isolation walls arranged between two adjacent rows of vertical transistors in a second direction, wherein the second direction is perpendicular to the first direction; wherein
a first distance between the gate dielectric layers of a first row of transistor and the isolation wall located adjacent to a first side of the first row of transistors is greater than 5 nm; and
a second distance between the gate dielectric layers of a first row of transistor and the isolation wall located adjacent to a second side of the first row of transistors is greater than 0 nm, the second side is opposite to the first side in the second direction.

7. The memory device of claim 6, further comprising:
an array of storage units coupled with the transistors, respectively;
wherein the storage units arranged at two sides of the isolation wall are misaligned with each other.

8. The memory device of claim 3, wherein
the first conductive layer, the second conductive layer, and the third conductive layer have an equal thickness along the first direction;
a thickness of the second conductive layer is greater than a thickness of the first conductive layer and a thickness of the third conductive layer along the first direction; and
a thickness of the second conductive layer is greater than or equal to a thickness of the first conductive layer along the first direction.

9. A memory device, comprising:
an array of transistors that are parallelly connected and extending along a first direction;
word lines each coupled to a row of the transistors arranged along a third direction; and
first isolation walls arranged in an alternating pattern with the word lines at a second direction, wherein the first direction, the third direction, and the second direction are perpendicular to each other; wherein
the word lines comprise:
a first conductive layer coupled to the transistors; and
a second conductive layer coupled to the transistors and isolated with the first conductive layer by a first dielectric layer along the first direction.

10. The memory device of claim 9, wherein
the first conductive layer is coupled with a first electrical source; and
the second conductive layer is coupled with a second electrical source having a different electrical level with the first electrical source.

11. The memory device of claim 9, further comprising:
a third conductive layer formed above a first side of the second conductive layer, the first side is away from the first conductive layer; and
a second dielectric layer located between the second conductive layer and the third conductive layer; wherein
the first conductive layer is coupled with a first electrical source;
the second conductive layer is coupled with a second electrical source; and
the third conductive layer is coupled with a third electrical source;
wherein the second electrical source has a different electrical level than the first electrical source or the third electrical source.

12. The memory device of claim 9, wherein
the transistor comprises a semiconductor layer extending along the first direction and a gate dielectric layer located between the semiconductor layer and the word line coupled with the transistor; and
the memory device further comprises isolation walls arranged between two adjacent rows of vertical transistors in a second direction, wherein the second direction is perpendicular to the first direction and the third direction.

13. A method for fabricating a memory device, comprising:
forming an array of transistors extending along a first direction, each transistor comprising a semiconductor layer and a source region and a drain region located at two opposite end of the semiconductor layer;
forming a gate stack structure coupled with the semiconductor layer and covering a middle region of the semiconductor layer between the source region and the drain region; wherein
the gate stack structure comprises:
a first conductive layer coupled to the transistors;
a second conductive layer coupled to the transistors and located above the first conductive layer along the first direction; and
a first dielectric layer located between the first conductive layer and the second conductive layer.

14. The method of claim 13, wherein the gate stack structure comprises:
a third conductive layer formed above a first side of the second conductive layer, the first side is away from the first conductive layer; and
a second dielectric layer located between the second conductive layer and the third conductive layer.

15. The method of claim 13, wherein forming the gate stack structure comprises:
forming a stacked structure comprising a first sacrificial layer, a second sacrificial layer, and the first dielectric layer located between the first sacrificial layer and the second sacrificial layer; and
replacing the first sacrificial layer and the second sacrificial layer with a conductive material to form the first conductive layer and the second conductive layer.

16. The method of claim 15, wherein forming the array of transistors comprises:
forming holes penetrating the stacked structure along the first direction; and
filling the holes with the semiconductor layer and gate dielectric layers located between the semiconductor layer and the stacked structure.

17. The method of claim 16, further comprising:
forming bit lines coupled to source regions or drain regions of the transistors and extending along a second direction, wherein the second direction is perpendicular to the first direction.

18. The method of claim 17, further comprising:
forming an array of storage units coupled with the transistors, respectively; wherein
the bit lines locate on a first side of the transistors; and
the storage units locate on a second side of the transistors opposite to the first side along the first direction.

19. The method of claim 17, further comprising:
forming an array of storage units coupled with the transistors, respectively; wherein
the bit lines and the storage units are located on a first side and a second side of the transistors, the second side being opposite to the first side along the first direction; and
the bit lines and the storage units are arranged in an alternating pattern on each side.

20. The method of claim 16, further comprising:
forming first isolation walls arranged between two adjacent rows of vertical transistors at a second direction, wherein the second direction is perpendicular to the first direction.
